(19) United States
(12) Patent Application Publication
(10) Pub. No.: US 2026/0098907 A1
(43) Pub. Date: Apr. 9, 2026

(54) BATTERY MANAGEMENT SYSTEM AND METHOD FOR EXTENDING BATTERY LIFETIME

(71) Applicant: Talent Innovative Circular Energy Technology CO.,LTD., TAIPEI CITY (TW)

(72) Inventors: CHUN-HUNG CHOU, TAIPEI CITY (TW); KUO-JUI HUANG, TAIPEI CITY (TW)

(21) Appl. No.: 19/014,145

(22) Filed: Jan. 8, 2025

(30) Foreign Application Priority Data
Oct. 7, 2024 (TW) 113138026

(51) Int. Cl. G01R 31/389; G01R 31/3842; H01M 10/42; H01M 10/44; H02J 7/00

(52) U.S. Cl. CPC G01R 31/389; G01R 31/3842; H01M 10/425; H01M 10/44; H02J 7/927; H01M 2010/4271

(57) ABSTRACT

A battery management system and method for extending battery lifetime is provided. In a test mode, the battery management system controls a charging frequency of a battery cell according to a plurality of pulse wave modulation signals respectively within a plurality of time intervals. The battery management system monitors impedances of the battery cell respectively within the plurality of time intervals or a plurality of capacitance ranges. The battery management system compares the impedances with each other to select one of the impedances, and sets a frequency of the pulse wave modulation signal that is outputted for controlling the charging frequency of the battery cell such that the battery cell has the selected impedance, as a practical frequency in a practical use mode. As a result, an increase in the impedance of the battery cell is delayed so as to extend lifetime of the battery cell.

### CROSS-REFERENCE TO RELATED PATENT APPLICATION

This application claims the benefit of priority to Taiwan Patent Application No. 113138026 filed on Oct. 7, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a battery, and more particularly to a battery management system and method for extending battery lifetime.

### BACKGROUND OF THE DISCLOSURE

With the development of technology related to electric vehicles, more and more people are showing willingness to purchase electric vehicles. The most critical factor by which use of the electric vehicles are affected is the lifetime of batteries used by the electric vehicles. As time within which the batteries are used in the electric vehicles increases, the batteries of the electric vehicles gradually experience degradation, and capacities of the batteries are gradually decreased.

### SUMMARY OF THE DISCLOSURE

In response to the above-referenced technical inadequacies, the present disclosure provides a battery management system for extending battery lifetime. The battery management system includes a battery monitoring circuit, a control circuit and a balancing circuit. The battery monitoring circuit is connected to a battery cell. The control circuit is connected to the battery monitoring circuit. The balancing circuit is connected to the battery cell and the control circuit. In a test mode, the control circuit is configured to output a plurality of pulse wave modulation signals to the balancing circuit respectively within a plurality of time intervals. In a test mode, the balancing circuit is configured to control a charging frequency of the battery cell according to a plurality of frequencies of the plurality of pulse wave modulation signals respectively within the plurality of time intervals. In the test mode, the battery monitoring circuit is configured to monitor and output a plurality of alternating current (AC) impedances of the battery cell respectively within the plurality of time intervals. In the test mode, the control circuit is configured to compare the plurality of AC impedances with each other to select one of the plurality of AC impedances. In the test mode, the control circuit is configured to set the frequency of the pulse wave modulation signal that is outputted for controlling the charging frequency of the battery cell, such that the battery cell is charged to have the one of the plurality of AC impedances as a practical frequency. In a practical use mode, the control circuit is configured to output the pulse wave modulation signal having the practical frequency. In the practical use mode, the balancing circuit controls the charging frequency of the battery cell according to the practical frequency of the pulse wave modulation signal for reducing a reversible impedance of the battery cell.

In order to solve the above-mentioned problems, one of the technical aspects adopted by the present disclosure is to provide a battery management method for extending battery lifetime. The battery management method includes processes of: in a test mode, generating a plurality of pulse wave modulation signals respectively within a plurality of time intervals, wherein a plurality of frequencies of the plurality of pulse wave modulation signals are different from each other; in the test mode, controlling a charging frequency of the battery cell according to the plurality of frequencies of the plurality of pulse wave modulation signals respectively within the plurality of time intervals; in the test mode, monitoring a plurality of alternating current (AC) impedances of the battery cell respectively within the plurality of time intervals; in the test mode, comparing the plurality of AC impedances with each other to select one of the plurality of AC impedances, and setting the frequency of the pulse wave modulation signal that is outputted for controlling the charging frequency of the battery cell such that the battery cell is charged to have the one of the plurality of AC impedances as a practical frequency; and, in a practical use mode, generating the pulse wave modulation signal having the practical frequency, and controlling the charging frequency of the battery cell according to the practical frequency of the pulse wave modulation signal.

As described above, the present disclosure provides the battery management system and the method for extending the battery lifetime. The battery management system of the present disclosure is a system used to manage the battery cell (including a plurality of batteries) in the battery pack. The battery management system and method of the present disclosure is capable of monitoring the plurality of AC impedances of the battery cell being charged respectively at the plurality of frequencies that are different from each other. The battery management system and method of the present disclosure selects one of the plurality of AC impedances according to practical requirements, and sets the frequency at which the battery cell is charged to have the selected AC impedance as the practical frequency.

In the practical use mode, the battery management system and method of the present disclosure generates the pulse wave modulation signal having the practical frequency, and charges the battery cell according to the pulse wave modulation signal having the practical frequency. In particular, the battery management system and method of the present disclosure is capable of charging the battery cell to have the smallest impedance at the practical frequency.

Therefore, the battery management system and method of the present disclosure is capable of effectively reducing the reversible impedance of the battery cell so as to reduce power consumption and heat that are generated by the battery pack, thereby extending the lifetime of the battery pack.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a circuit diagram of a battery management system for extending battery lifetime according to a first embodiment of the present disclosure;

FIG. 2 is a flowchart diagram of steps of a battery management method for extending the battery lifetime according to the first embodiment of the present disclosure;

FIG. 3 is a circuit diagram of a battery management system for extending battery lifetime according to a second embodiment of the present disclosure;

FIG. 4 is a schematic diagram showing decrease in an initial impedance of a battery cell that is charged for one cycle in the battery management system and the method according to the first and second embodiments of the present disclosure;

FIG. 5 is a schematic diagram showing decrease in an initial impedance of a battery cell that is charged for one cycle in the battery management system and the method according to the first and second embodiments of the present disclosure;

FIG. 6 is a schematic diagram showing decrease in an initial impedance of a battery cell that is charged for one cycle in the battery management system and the method according to the first and second embodiments of the present disclosure;

FIG. 7 is a schematic diagram showing decrease in an initial impedance of a battery cell that is charged for one cycle in the battery management system and the method according to the first and second embodiments of the present disclosure; and

FIG. 8 is a schematic diagram of attenuation in an impedance of a battery cell before and after the battery management system and the method are applied on the battery cell according to the first and second embodiments of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

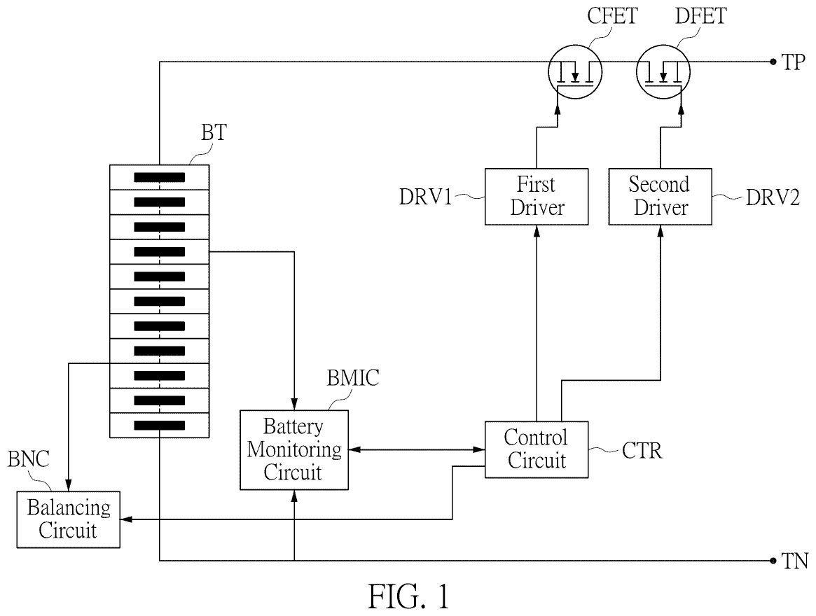

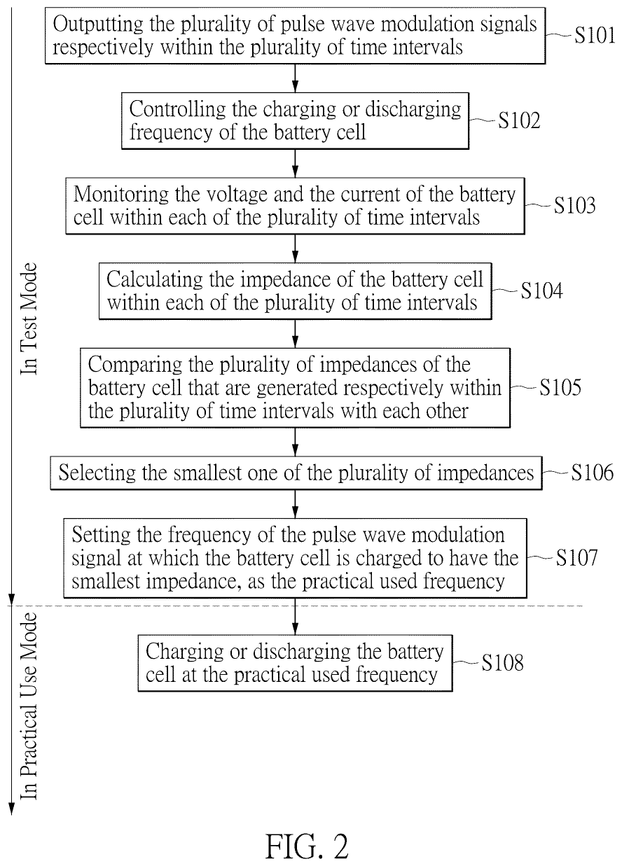

Reference is made to FIG. 1 and FIG. 2, in which FIG. 1 is a circuit diagram of a battery management system for extending battery lifetime according to a first embodiment of the present disclosure, and FIG. 2 is a flowchart diagram of steps of a battery management method for extending the battery lifetime according to the first embodiment of the present disclosure.

The battery management system of the present disclosure and a battery cell BT as shown in FIG. 1 may be included in a battery pack. The battery cell BT may include a plurality of batteries that may be connected in series with each other.

As shown in FIG. 1, in the first embodiment, the battery management system of the present disclosure includes a battery monitoring circuit BMIC, a control circuit CTR and a balancing circuit BNC. For example, the control circuit CTR may include a controller, a microprocessor, and so on.

In addition, the battery management system of the present disclosure may further include a charging-side transistor CFET, a discharging-side transistor DFET, a first driver DRV1, a second driver DRV2 and other circuit components.

The battery monitoring circuit BMIC is connected to the battery cell BT. The control circuit CTR is connected to the battery monitoring circuit BMIC, the balancing circuit BNC, the first driver DRV1 and the second driver DRV2. The charging-side transistor CFET may be any type of transistor or a switch component. A first terminal of the charging-side transistor CFET is connected to a positive terminal of the battery cell BT. A control terminal of the charging-side transistor CFET is connected to an output terminal of the first driver DRV1. An input terminal of the first driver DRV1 is connected to an output terminal of the control circuit CTR.

The discharging-side transistor DFET may be any type of transistor or switch component. A first terminal of the discharging-side transistor DFET is connected to a second terminal of the charging-side transistor CFET. A second terminal of the discharging-side transistor DFET is connected to a positive terminal TP of the battery pack. A control terminal of the discharging-side transistor DFET is connected to an output terminal of the second driver DRV2. An input terminal of the second driver DRV2 is connected to the output terminal of the control circuit CTR.

In the first embodiment, the battery management method of the present disclosure may include processes S101 to S108 shown in FIG. 2. The battery management system shown in FIG. 1 is applicable to perform processes S101 to S108 shown in FIG. 2, which is described specifically as follows.

In a test mode, the control circuit CTR outputs a plurality of pulse wave modulation signals to the balancing circuit BNC respectively within a plurality of time intervals (in process S101 of FIG. 2), and the balancing circuit BNC uses the plurality of pulse wave modulation signals respectively within the plurality of time intervals. The plurality of time intervals described herein may be replaced with a plurality of capacitance ranges of the battery cell BT.

The balancing circuit BNC controls a charging frequency of the battery cell BT according to frequencies of a plurality of pulse waves of the plurality of pulse wave modulation signals respectively within the plurality of time intervals (in process S102 of FIG. 2). That is, the frequencies of the plurality of pulse wave modulation signals are, respectively, within the plurality of time intervals, and used as the charging frequency of the battery cell BT. In the test mode, the frequencies of the plurality of pulse waves of each of the plurality of pulse wave modulation signals are the same as each other.

In the test mode, the battery monitoring circuit BMIC monitors and calculates a plurality of alternating current (AC) impedances of the battery cell BT respectively within the plurality of time intervals. For example, within each of the plurality of time intervals, the battery monitoring circuit BMIC monitors a voltage and a current of the battery cell BT (in process S103 of FIG. 2), and the control circuit CTR calculates the AC impedance of the battery cell BT according to the voltage and the current of the battery cell BT (in process S104 of FIG. 2). For convenience of explanation, the voltage of the battery cell BT described herein is a sum of voltages respectively of the plurality of batteries included in the battery cell BT.

It is worth noting that, in the test mode, the frequencies of the plurality of pulse waves of the plurality of pulse wave modulation signals that are outputted by the control circuit CTR respectively within the plurality of time intervals are different from each other for testing the plurality of AC impedances of the battery cell BT being charged respectively at the different frequencies.

It should be understood that, energy loss of the battery pack is affected by an internal impedance of the battery cell BT of the battery pack. The larger the internal impedance of the battery cell BT is, the higher the power consumption and heat of the battery pack that are generated in the battery pack.

Therefore, in the test mode, the control circuit CTR compares the plurality of AC impedances of the battery cell BT that are generated respectively within the plurality of time intervals with each other (in process S105 of FIG. 2). That is, the control circuit CTR compares the plurality of AC impedances of the battery cell BT that are generated when the plurality of pulse wave modulation signals are respectively outputted to the balancing circuit BNC with each other. The control circuit CTR selects one of the plurality of AC impedances. For example, the control circuit CTR selects a smallest one of the plurality of AC impedances (in process S106 of FIG. 2).

It is worth noting that, in the test mode, the control circuit CT sets the frequency of the pulse wave modulation signal that is outputted for controlling the charging frequency of the battery cell BT, such that the battery cell BT is charged to have the selected AC impedance such as the smallest one of the plurality of AC impedances, as a practical frequency (in process S107 of FIG. 2). That is, when the balancing circuit BNC controls the battery cell BT to be charged at the practical frequency, the battery cell BT has the selected AC impedance such as the smallest one of the plurality of AC impedances.

Calculation of a direct current (DC) impedance, otherwise referred to as a DC internal impedance, of the battery cell BT is described in detail as follows.

Within each of the plurality of time intervals, the control circuit CTR controls the balancing circuit BNC to output a DC signal to the battery cell BT, and the battery cell BT is discharged at a first discharging frequency or charged at a first charging frequency for a first period of time. After the first period of time ends, the battery monitoring circuit BMIC monitors the voltage and the current of the battery cell BT at a first time point within each of the plurality of time intervals.

Within each of the plurality of time intervals, the control circuit CTR controls the balancing circuit BNC to output the DC signal to the battery cell BT, and the battery cell BT is discharged at a second discharging frequency or charged at a second charging frequency for a second period of time. After the second period of time ends, the battery monitoring circuit BMIC monitors the voltage and the current of the battery cell BT at a second time point within each of the plurality of time intervals.

Then, the control circuit CTR subtracts the voltage of the battery cell BT at the second time point from the voltage of the battery cell BT at the first time point to obtain a first DC calculated value. The control circuit CTR subtracts the current of the battery cell BT at the first time point from the current of the battery cell BT at the second time point to obtain a second DC calculated value. The control circuit CTR divides the first DC calculated value by the second DC calculated value to obtain the DC impedance, otherwise referred to as the DC internal impedance, of the battery cell BT. The above-mentioned calculation of the DC impedance of the battery cell BT is represented by the following equation:

$$DC IR = \frac{V 1 - V 2}{I 2 - I 1} ,$$

wherein DCIR represents the DC impedance of the battery cell BT, V1 represents the voltage of the battery cell BT at the first time point, V2 represents the voltage of the battery cell BT at the second time point, I2 represents the current of the battery cell BT at the second time point, and I1 represents the current of the battery cell BT at the first time point.

It should be understood that, the first time point and the second time point refer to any two different time points, rather than two specified time points.

Calculation of the AC impedance or called an internal AC impedance of the battery cell BT is described in detail as follows.

Within each of the plurality of time intervals, the control circuit CTR controls the balancing circuit BNC to output a first AC signal to the battery cell BT, and the battery cell BT is discharged at the first discharging frequency or charged at the first charging frequency for the first period of time. After the first period of time ends, the battery monitoring circuit BMIC monitors the voltage and the current of the battery cell BT at the first time point within each of the plurality of time intervals.

Within each of the plurality of time intervals, the control circuit CTR controls the balancing circuit BNC to output the DC signal to the battery cell BT, and the battery cell BT is discharged at the second discharging frequency or charged at the second charging frequency for the second period of time. After the second period of time ends, the battery monitoring circuit BMIC monitors the voltage and the current of the battery cell BT at the second time point within each of the plurality of time intervals.

Then, the control circuit CTR subtracts the voltage of the battery cell BT at the second time point from the voltage of the battery cell BT at the first time point to obtain a first AC calculated value. The control circuit CTR subtracts the current of the battery cell BT at the first time point from the current of the battery cell BT at the second time point to obtain a second AC calculated value. The control circuit CTR divides the first AC calculated value by the second AC calculated value to obtain the AC impedance, otherwise referred to as the AC internal impedance, of the battery cell BT. The above-mentioned calculation of the AC impedance of the battery cell BT is represented by the following equation:

$$AC IR = \frac{V 1 - V 2}{I 2 - I 1} ,$$

wherein ACIR represents the AC impedance of the battery cell BT, V1 represents the voltage of the battery cell BT at the first time point, V2 represents the voltage of the battery cell BT at the second time point, I2 represents the current of the battery cell BT at the second time point, and I1 represents the current of the battery cell BT at the first time point.

The control circuit CTR may compare the plurality of AC impedances of the battery cell BT being charged respectively at the plurality of frequencies with each other to determine the smallest one of the plurality of AC impedances of the battery cell BT. The control circuit CTR may compare the plurality of DC impedances of the battery cell BT being charged respectively at the plurality of frequencies with each other to determine a smallest one of the plurality of DC impedances of the battery cell BT. The control circuit CTR may add up the smallest one of the plurality of AC impedances and the smallest one of the plurality of DC impedances of the battery cell BT to obtain a total impedance. The control circuit CTR may determine the practical frequency according to the total impedance.

For example, the control circuit CTR may look for a plurality of reference total impedances and a plurality of reference duties that respectively correspond to the plurality of reference total impedances on a lookup table. The control circuit CTR may calculate the practical frequency according to the reference used duty corresponding to the reference total impedance being equal to the total impedance.

More precisely, a plurality of reference value groups that respectively correspond to different types of batteries composed of different materials are stored in the lookup table. Each of the plurality of reference value groups includes the plurality of reference total impedances and the plurality of reference duties. The plurality of reference duties respectively correspond to the plurality of reference total impedances. The different types of batteries respectively correspond to the plurality of reference value groups that are different from each other. The control circuit CTR determines type or composition material of the battery cell BT and accordingly obtains one of the plurality of reference value groups. The control circuit CTR obtains the reference used duty corresponding to the reference total impedance being equal to the total impedance from the one of the plurality of reference value groups. The control circuit CTR calculates the practical frequency according to the obtained reference used duty.

It should be understood by those skilled in the art that, a working period of the pulse wave of the pulse wave modulation signal is divided by an entire period to obtain a duty cycle of the pulse wave of a pulse wave modulation signal. The entire period is a sum of the working period and a non-working period of the pulse wave of the pulse wave modulation signal. A frequency of the pulse wave of the pulse wave modulation signal is a reciprocal of the entire period of the pulse wave of the pulse wave modulation signal. Therefore, the control circuit CTR calculates the practical frequency according to the obtained reference used duty.

For example, the control circuit CTR may, based on a remaining power percentage or a state of charge (SOC) of the battery cell BT of the battery pack or a tested battery pack and a composition material coefficient corresponding to the composition material of the battery cell BT, determine the reference used duty for calculation of the practical frequency, which is represented by the following equation:

$$DT ( \% ) = ( 100 - SOC ) \times M ,$$

wherein DT represents the reference used duty, SOC represents the remaining power percentage or the state of charge (SOC) of the battery cell BT, and M represents the composition material coefficient corresponding to the composition material of the battery cell BT.

After the battery management system and method of the present disclosure determines or calculates the practical frequency in the test mode, the battery management system and method of the present disclosure may enter the practical use mode.

In the practical use mode, the control circuit CTR instructs the balancing circuit BNC to maintain the charging frequency of the battery cell BT to be equal to the practical frequency (in process S108 of FIG. 2). For example, the control circuit CTR outputs the pulse wave modulation signal in which each of the plurality of pulse waves has the practical frequency to the balancing circuit BNC, and the balancing circuit BNC controls the charging frequency of the battery cell BT according to the practical frequency of the pulse wave modulation signal.

The control circuit CTR may output a first control signal to the first driver DRV1 and output a second control signal to the second driver DRV2, according to the voltage and the current of the battery cell BT that are monitored by the battery monitoring circuit BMIC. In particular, the control circuit CTR may output the first control signal to the first driver DRV1 and output the second control signal to the second driver DRV2, according to the voltage and the current of the battery cell BT being charged at the practical frequency in the practical use mode. The first driver DRV1 drives the charging-side transistor CFET according to the first control signal. The second driver DRV2 drives the discharging-side transistor DFET according to the second control signal.

The control circuit CTR selects one of the plurality of impedances of the battery cell BT being charged respectively at the plurality of frequencies of the plurality of pulse wave modulation signals. The control circuit CTR sets the frequency at which the battery cell BT is charged to have the selected impedance as the practical frequency. In the practical use mode, the control circuit CTR instructs the balancing circuit BNC to maintain the charging frequency of the battery cell BT to be equal to the practical frequency such that the battery cell BT is maintained to have the selected impedance for controlling power consumption of the battery pack.

For example, in the practical use mode, the balancing circuit BNC maintains the charging frequency of the battery cell BT to be equal to the practical frequency such that the battery cell BT is maintained to have the smallest one of the plurality of impedances of the battery cell BT (in processes S106 and S107 of FIG. 2). As a result, the power consumption of the battery pack is most effectively reduced, thereby extending lifetime of the battery pack.

In addition, a discharging frequency of the battery cell BT may be controlled by an external transformer or an external voltage converting device.

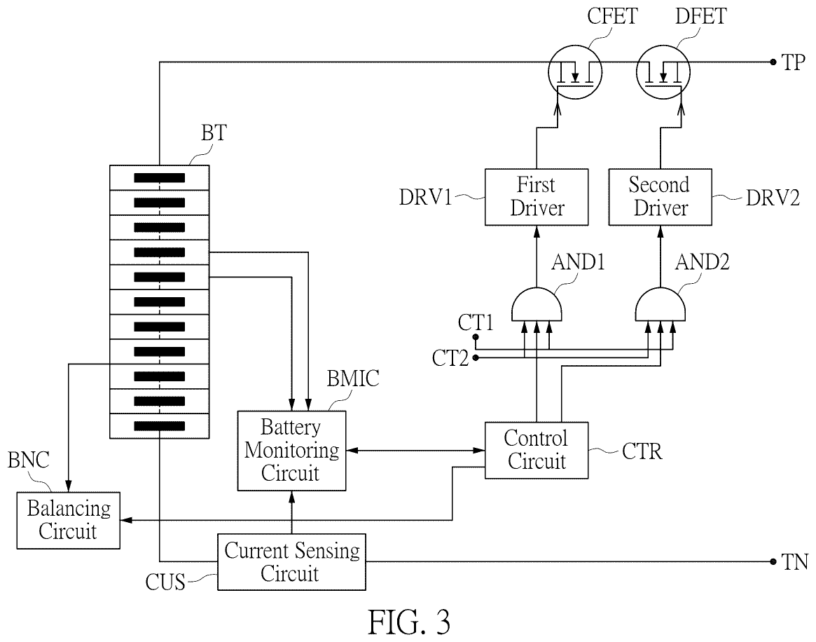

Reference is made to FIG. 3, which is a circuit diagram of a battery management system for extending battery lifetime according to a second embodiment of the present disclosure.

A difference between the second and first embodiments is that, the battery management system of the second embodiment of the present disclosure further includes a current sensing circuit CUS, a first gate AND1 and a second gate AND2. In practice, the first gate AND1 and the second gate AND2 may be replaced with other types of logic gates or other circuit components, or may be omitted.

The current sensing circuit CUS is connected to the battery cell BT and the battery monitoring circuit BMIC. For example, the current sensing circuit CUS may be connected between a negative terminal of the battery cell BT and a negative terminal TN of the battery pack.

Within each of the plurality of time intervals, the current sensing circuit CUS senses the current of the battery cell BT, and the battery monitoring circuit BMIC monitors the current sensed by the current sensing circuit CUS.

In addition, in the second embodiment of the present disclosure, the battery monitoring circuit BMIC may not only monitor the current and the voltage of the battery cell BT, but also monitor a temperature of the battery cell BT.

The control circuit CTR may determine whether or not the current of the battery cell BT is larger than a current threshold, determine whether or not the voltage of the battery cell BT is higher than a voltage threshold, and/or determine whether or not the temperature of the battery cell BT is larger than a temperature threshold.

When the control circuit CTR determines that the current of the battery cell BT is larger than the current threshold, the voltage of the battery cell BT is higher than the voltage threshold or the temperature of the battery cell BT is larger than the temperature threshold, the control circuit CTR may output a protection logic signal CT2 at a first reference level such as a high level.

Conversely, when the control circuit CTR determines that the current of the battery cell BT is not larger than the current threshold, the voltage of the battery cell BT is not higher than the voltage threshold and the temperature of the battery cell BT is not larger than the temperature threshold, the control circuit CTR may output the protection logic signal CT2 at a second reference level such as a low level.

When the control circuit CTR determines that the frequencies of the pulse wave modulation signal are outputted for controlling the charging frequency of the battery cell BT, the control circuit CTR may output a frequency control starting signal CT1 at the first reference level such as the high level. Conversely, when the control circuit CTR determines that the frequencies of the pulse wave modulation signal are not outputted for controlling the charging frequency of the battery cell BT, the control circuit CTR may output the frequency control starting signal CT1 at the second reference level such as the low level.

Third input terminals of the first gate AND1 may respectively receive the frequency control starting signal CT1, the protection logic signal CT2 and the first control signal. Third input terminals of the second gate AND2 may respectively receive the frequency control starting signal CT1, the protection logic signal CT2 and the second control signal.

The first driver DRV1, according to a first logic gate from an output terminal of the first gate AND1, outputs a first driving signal to the control terminal of the charging-side transistor CFET for driving the charging-side transistor CFET. The second driver DRV2, according to a second logic gate from an output terminal of the second gate AND2, outputs a second driving signal to the control terminal of the discharging-side transistor DFET for driving the discharging-side transistor DFET. In this manner, a charging current that flows from an external power source through the positive terminal TP of the battery pack into the battery pack and then flows sequentially through the charging-side transistor CFET and the discharging-side transistor DFET to the battery cell BT is controlled, and a discharging current that flows through the charging-side transistor CFET and the discharging-side transistor DFET is controlled.

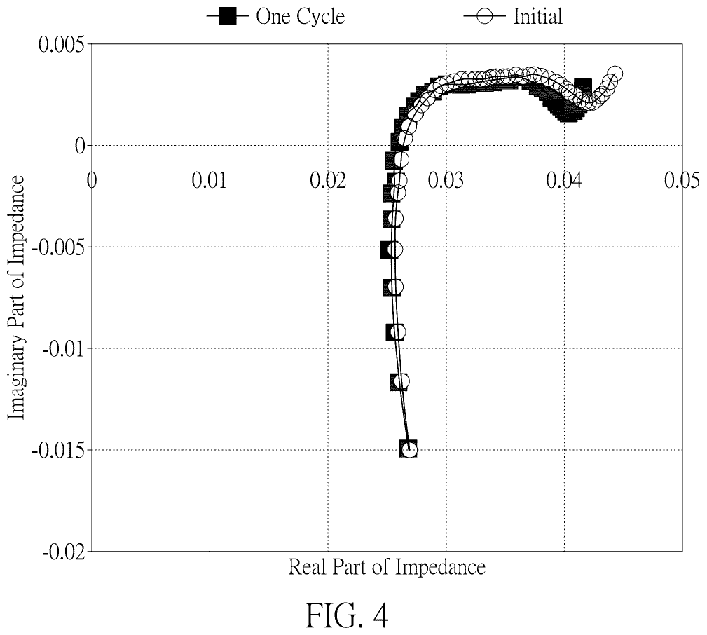

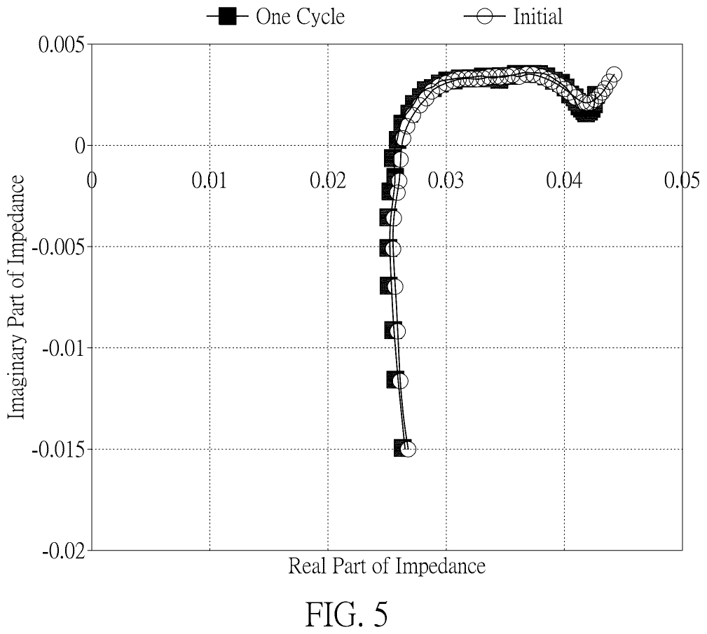

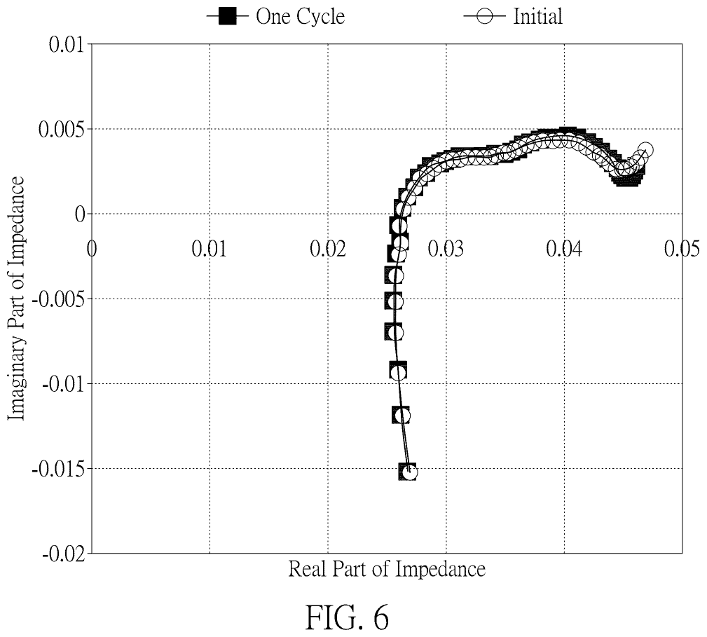

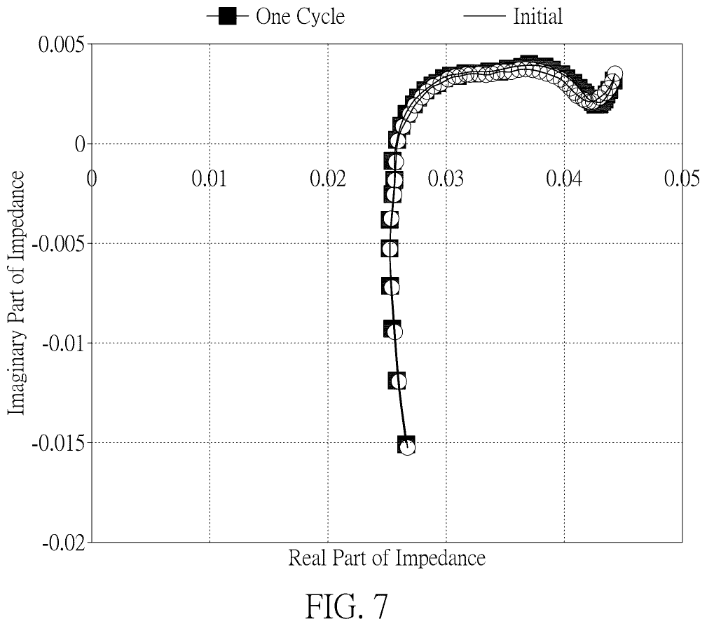

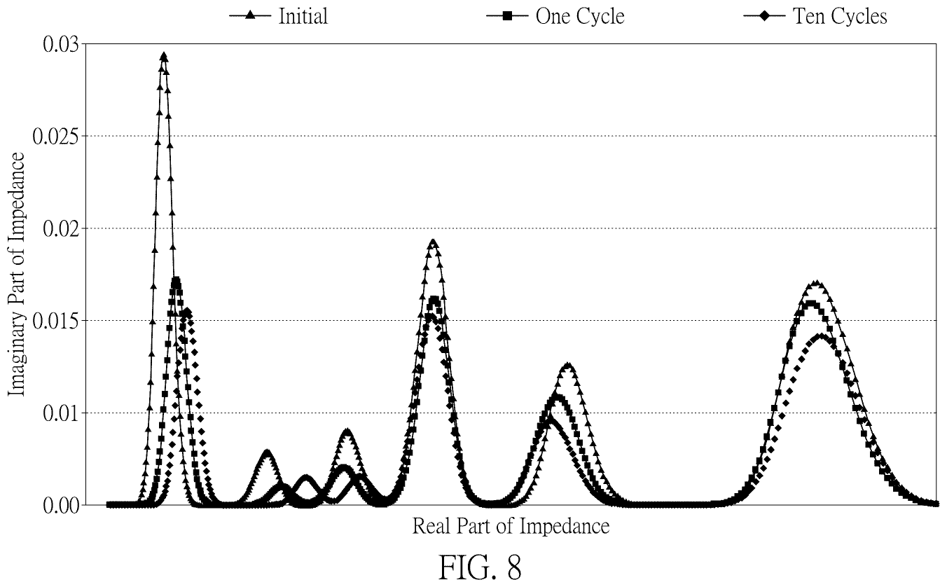

Reference is made to FIG. 4 to FIG. 8, in which FIG. 4 to FIG. 7 are schematic diagrams of decrease in an initial impedance of a battery cell that is charged for one cycle in the battery management system and the method according to the first and second embodiments of the present disclosure, and FIG. 8 is a schematic diagram of attenuation in an impedance of a battery cell before and after the battery management system and the method are applied on the battery cell according to the first and second embodiments of the present disclosure.

The impedances of different types of the battery cells BT are respectively shown in FIG. 4 to FIG. 7. Before the battery management system and method of the present disclosure are used on the battery cells BT, the battery cells BT respectively have initial impedances shown in FIG. 4 to FIG. 7. As shown in FIG. 4 to FIG. 8, the states of health (SOH) of each of the battery cells BT is 90%.

It is worth noting that, as shown in FIG. 4 to FIG. 7, when the battery management system and method of the present disclosure are used on the battery cells BT such that each of the battery cells BT is charged at the practical frequency for one cycle, the impedance of each of the battery cells BT is reduced and smaller than the initial impedance thereof.

When the battery cell BT is charged at the practical frequency for more cycles, the impedance of the battery cell BT is more significantly reduced. As shown in FIG. 8, when the battery cell BT is charged at the practical frequency for ten cycles, attenuation in the impedance of the battery cell BT is increased, and the impedance of the battery cell BT is reduced to a lower value. As a result, unnecessary power consumption of the battery pack is effectively reduced.

In conclusion, the present disclosure provides the battery management system and the method for extending the battery lifetime. The battery management system of the present disclosure is a system used to manage the battery cell (including the plurality of batteries) in the battery pack. The battery management system and method of the present disclosure is capable of monitoring the plurality of AC impedances of the battery cell being charged respectively at the plurality of frequencies that are different from each other. The battery management system and method of the present disclosure selects one of the plurality of AC impedances according to practical requirements, and sets the frequency at which the battery cell is charged to have the selected AC impedance as the practical frequency.

In the practical use mode, the battery management system and method of the present disclosure generates the pulse wave modulation signal having the practical frequency, and charges the battery cell according to the pulse wave modulation signal having the practical frequency. In particular, the battery management system and method of the present disclosure is capable of charging the battery cell to have the smallest impedance at the practical frequency.

Therefore, the battery management system and method of the present disclosure is capable of effectively reducing the reversible impedance of the battery cell so as to reduce the power consumption and the heat that are generated by the battery pack, thereby extending the lifetime of the battery pack.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A battery management system for extending battery lifetime, comprising:
a battery monitoring circuit connected to a battery cell;
a control circuit connected to the battery monitoring circuit; and
a balancing circuit connected to the battery cell and the control circuit;
wherein, in a test mode, the control circuit is configured to output a plurality of pulse wave modulation signals to the balancing circuit respectively within a plurality of time intervals, and the balancing circuit is configured to control a charging frequency of the battery cell according to a plurality of frequencies of the plurality of pulse wave modulation signals respectively within the plurality of time intervals;
wherein, in the test mode, the battery monitoring circuit is configured to monitor and output a plurality of alternating current (AC) impedances of the battery cell respectively within the plurality of time intervals;
wherein, in the test mode, the control circuit is configured to compare the plurality of AC impedances with each other to select one of the plurality of AC impedances, and set the frequency of the pulse wave modulation signal that is outputted for controlling the charging frequency of the battery cell such that the battery cell is charged to have the one of the plurality of AC impedances as a practical frequency;
wherein, in a practical use mode, the control circuit is configured to output the pulse wave modulation signal having the practical frequency, and the balancing circuit controls the charging frequency of the battery cell according to the practical frequency of the pulse wave modulation signal for reducing a reversible impedance of the battery cell.

2. The battery management system according to claim 1, wherein, in the test mode, within each of the plurality of time intervals, the battery monitoring circuit is configured to monitor a voltage and a current of the battery cell, and the control circuit is configured to calculate the AC impedance of the battery cell according to the voltage and the current of the battery cell.

3. The battery management system according to claim 2, further comprising:
a sensing circuit connected to the battery monitoring circuit and the battery cell, and configured to sense and output the current of the battery cell to the battery monitoring circuit within each of the plurality of time intervals.

4. The battery management system according to claim 1, wherein the control circuit is configured to select a smallest one of the plurality of AC impedances, and set the frequency of the pulse wave modulation signal that is outputted for controlling the charging frequency of the battery cell such that the battery cell is charged to have the smallest one of the plurality of AC impedances as the practical frequency.

5. The battery management system according to claim 1, wherein the battery monitoring circuit is configured to monitor the plurality of AC impedances of the battery cell being charged respectively at the plurality of frequencies;
wherein the battery monitoring circuit is configured to monitor a plurality of direct current (DC) impedances of the battery cell being charged respectively at the plurality of frequencies;
wherein the control circuit is configured to add up a smallest one of the plurality of AC impedances and a smallest one of the plurality of DC impedances to obtain a total impedance, and configured to determine the practical frequency according to the total impedance.

6. The battery management system according to claim 5, wherein the control circuit is configured to look for a plurality of reference total impedances and a plurality of reference duties that respectively correspond to the plurality of reference total impedances on a lookup table, and configured to calculate the practical frequency according to the reference used duty corresponding to the reference total impedance being equal to the total impedance.

7. A battery management method for extending battery lifetime, comprising processes of:
in a test mode, generating a plurality of pulse wave modulation signals respectively within a plurality of time intervals, wherein a plurality of frequencies of the plurality of pulse wave modulation signals are different from each other;
in the test mode, controlling a charging frequency of the battery cell according to the plurality of frequencies of the plurality of pulse wave modulation signals respectively within the plurality of time intervals;
in the test mode, monitoring a plurality of alternating current (AC) impedances of the battery cell respectively within the plurality of time intervals;
in the test mode, comparing the plurality of AC impedances with each other to select one of the plurality of AC impedances, and setting the frequency of the pulse wave modulation signal that is outputted for controlling the charging frequency of the battery cell such that the battery cell is charged to have the one of the plurality of AC impedances as a practical frequency; and
in a practical use mode, generating the pulse wave modulation signal having the practical frequency, and controlling the charging frequency of the battery cell according to the practical frequency of the pulse wave modulation signal.

8. The battery management method according claim 7, further comprising processes of:
in the test mode, within each of the plurality of time intervals, monitoring a voltage and a current of the battery cell; and
in the test mode, within each of the plurality of time intervals, calculating the AC impedance of the battery cell according to the voltage and the current of the battery cell.

9. The battery management method according claim 7, further comprising processes of:
selecting a smallest one of the plurality of AC impedances; and
setting the frequency of the pulse wave modulation signal that is outputted for controlling the charging frequency of the battery cell such that the battery cell is charged to have the smallest one of the plurality of AC impedances, as the practical frequency.

10. The battery management method according claim 7, further comprising processes of:
monitoring the plurality of AC impedances of the battery cell being charged respectively at the plurality of frequencies;
monitoring a plurality of direct current (DC) impedances of the battery cell being charged respectively at the plurality of frequencies;
adding up a smallest one of the plurality of AC impedances and a smallest one of the plurality of DC impedances to obtain a total impedance; and
determining the practical frequency according to the total impedance.

11. The battery management method according claim 10, further comprising processes of:
looking for a plurality of reference total impedances and a plurality of reference duties that respectively correspond to the plurality of reference total impedances on a lookup table; and
calculating the practical frequency according to the reference used duty corresponding to the reference total impedance being equal to the total impedance.
